(19) United States
(12) Patent Application Publication
(10) Pub. No.: US 2003/0048617 A1
(43) Pub. Date: Mar. 13, 2003

(54) Card-type electronic circuit unit

(75) Inventor: Daijo Shibata, Fukushima-ken (JP)

Correspondence Address: Brinks Hofer Gilson & Lione, P.O. Box 10395, Chicago, IL, 60610, US

(73) Assignee: Alps Electric Co., Ltd.

(21) Appl. No.: 10/238,097

(22) Filed: Sep. 10, 2002

(30) Foreign Application Priority Data
Sep. 12, 2001 (JP) 2001-275970

(51) Int. Cl. H05K 1/14

(52) U.S. Cl. 361/737

(57) ABSTRACT

In a card-type electronic circuit unit, a case is constituted of first and second case portions, and these first and second case portions respectively include planar walls and annular side walls which extend in a perpendicular direction from outer peripheries of the walls. One of the first and second case portions is provided with a projection extending from an end of the side wall and the other of the first and second case portions is provided with a recess which is positioned on an end surface of the side wall. Since the first and second case portions are bonded to each other in the state that the projection is fitted into the recess thus forming the concave-convex fitting state, a creeping distance between inner and outer portions of the case can be elongated compared to the prior art. Accordingly, propagation of static electricity into the accommodating portion can be prevented and hence, rupture of an electric circuit on the circuit board can be reduced.

### BACKGROUND OF THE INVENTION

1. Field of the Invention

The present invention relates to a card-type electronic circuit unit which can be suitably used as an IC card, a PC card, a wireless card (memory card) and the like.

2. Description of the Related Art

With respect to a conventional card-type electronic circuit unit C2, the constitution of the unit C2 is explained in conjunction with FIG. 2 by taking a wireless card (memory card) served for short-distance wireless data communication (Bluetooth) as an example. A circuit board 51 formed of a rectangular printed circuit board or the like is provided with a desired conductive pattern not shown in the drawing. Further, various electric components 52 such as chip capacitors and resisters are mounted on the circuit board 51 thus forming a transmission/reception circuit which constitutes a desired electric circuit.

A rectangular parallelepiped case 53 made of synthetic resin is constituted of a first case portion 54 which forms a lower portion and a second case portion 55 which forms an upper portion. The case 53 is formed by combining these first and second case portions 54, 55 together.

In an accommodating portion 56 defined by the first and second case portions 54, 55, the circuit board 51 and the electric components 52 are accommodated.

Further, the first and second case portions 54, 55 are formed of molded products made of synthetic resin. The first case portion 54 includes a planar wall 54a, an annular side wall 54b which extends in a perpendicular direction from an outer periphery of the planar wall 54a, and a flat surface 54c which is positioned at an end of the side wall 54b. On the other hand, the second case portion 55 includes a planar wall 55a, an annular side wall 55b which extends in a perpendicular direction from an outer periphery of the planar wall 55a, and a flat surface 55c which is positioned at an end of the side wall 55b.

Further, in a state that the first and second case portions 54, 55 accommodate the circuit board 51 and the electric components 52 inside thereof, and the flat surfaces 54c, 55c are abutted onto each other. By jointing the flat surfaces 54c, 55c by welding using ultrasonic working while maintaining the above-mentioned abutting state, the first and second case portions 54, 55 are bonded to each other thus forming the case 53.

Further, the annular side walls 54b, 55b have suitable portions thereof partially welded to each other.

The card-type electronic circuit unit C2 having such a constitution can be inserted into and removed from an external device 57 of a personal computer or the like, for example and when the card-type electronic circuit unit C2 is inserted into the external device 57, a state in which the circuit board 51 is connected to the external device 57 is established.

Then, with the use of the card-type electronic circuit unit C2, data is transmitted from this external device 57 to other external device (not shown in the drawing) or this external device 57 receives data from another external device (not shown in the drawing) whereby data communication is performed between this external device 57 and the other external device.

Further, at the time of pulling our or inserting the card-type electronic circuit unit C2, the card-type electronic circuit unit C2 is held in a hand. In this state, static electricity easily propagates or flows into the accommodating portion 56 through the flat surfaces 54c, 55c of the first and the second case portions 54, 55 having a short creeping distance and hence, the electric circuit on the circuit board 51 is broken.

As described above, the conventional card-type electronic circuit unit has the drawback that since the flat surfaces 54c, 55c of the first and the second case portions 54, 55 are bonded to each other by abutting the flat surfaces 54c, 55c each other, static electricity easily propagates or flows into the accommodating portion 56 through the flat surfaces 54c, 55c of the first and second case portions 54, 55 having a short creeping distance and hence, the electric circuit on the circuit board 51 is broken.

### SUMMARY OF THE INVENTION

Accordingly, it is an object of the present invention to provide a card-type electronic circuit unit which can minimize the breakdown of an electric circuit by reducing the propagation of static electricity into a case by elongating a creeping distance.

As first means for solving the above-mentioned problem of the prior art, there is provided a card-type electronic circuit unit having the following constitution. That is, the card-type electronic circuit unit is capable of being inserted into or removed from an external device and includes a circuit board which is connectable to the external device, electronic components which are mounted on the circuit board and constitute a given electric circuit, and a case which accommodates the electric components and the circuit board therein, the case is constituted of first and second case portions, the first and second case portions respectively include planar walls and annular side walls which extend in a perpendicular direction from outer peripheries of the walls, one of the first and the second case portions includes a projection extending from an end of the side wall, the other of the first and the second case portions includes a recess positioned at an end surface of the side wall, and the first and the second case portions are bonded to each other in a state that the projection is fitted into the recess.

As the second means for solving the drawback of the prior art, there is provided a constitution in which the projection and the recess are formed on entire peripheries of the annular side walls.

As the third means for solving the drawback of the prior art, there is provided a constitution in which the first case portion includes the projection, the side wall of the second case portion which includes the recess includes a projecting wall which extends along an inner side of the side wall of the first case portion, and the circuit board is sandwiched by an end of the projecting wall and the first case portion.

As the fourth means for solving the drawback of the prior art, there is provided a constitution in which the first case portion includes the projection, the side wall of the second case portion which includes the recess includes a projecting wall which extends along an inner side of the side wall of the first case portion, and an end of the projecting wall is brought into contact with a conductive pattern for grounding which is formed on the circuit board.

### BRIEF EXPLANATION OF DRAWINGS

FIG. 1 is a cross-sectional view of an essential part according to a card-type electronic circuit unit according to the present invention; and

FIG. 2 is a cross-sectional view of an essential part according to a conventional card-type electronic circuit unit.

### DESCRIPTION OF PREFERRRED EMBODIMENT

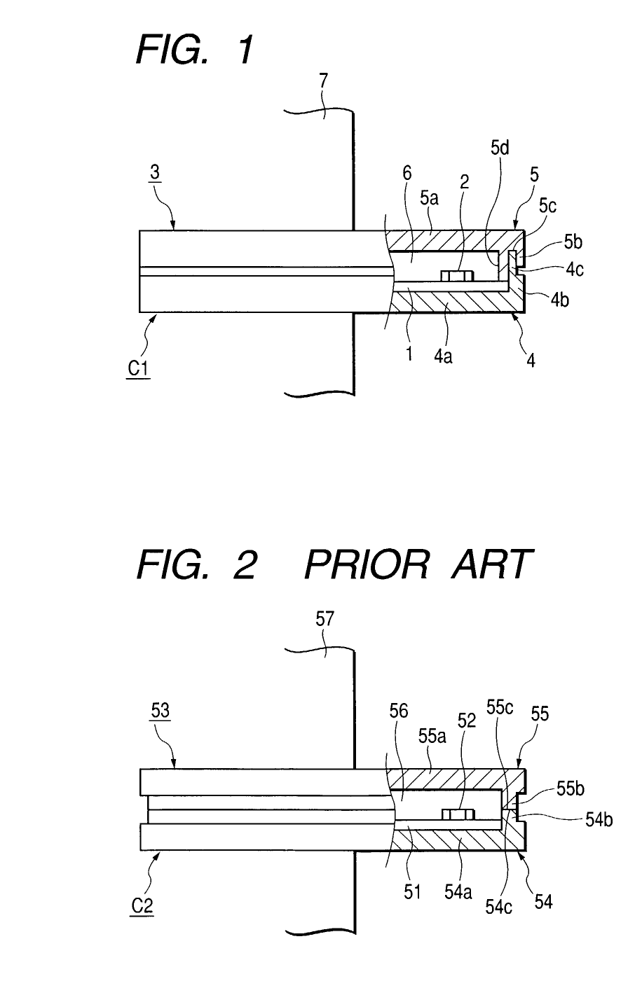

A preferred embodiment of the present invention is explained hereinafter in conjunction with FIG. 1.

With respect to a card-type electronic circuit unit C1 of the present invention, the constitution of the unit C1 is explained in conjunction with FIG. 1 by taking a wireless card (memory card) served for short-distance wireless data communication (Bluetooth) as an example. A circuit board 1 formed of a rectangular printed circuit board or the like is provided with a desired conductive pattern not shown in the drawing. Further, various electric components 2 such as chip capacitors and resisters are mounted on the circuit board 1 thus forming a transmission/reception circuit which constitutes a desired electric circuit.

A rectangular parallelepiped case 3 made of synthetic resin is constituted of a first case portion 4 which forms a lower portion and a second case portion 5 which forms an upper portion. The case 3 is formed by combining these first and second case portions 4, 5 together.

In an accommodating portion 6 defined by the first and second case portions 4, 5, the circuit board 1 and the electric components 2 are accommodated.

Further, the first and second case portions 4, 5 are formed of molded products made of synthetic resin. The first case portion 4 includes a planar wall 4a, a rectangular annular side wall 4b which extends in a perpendicular direction from an outer periphery of the planar wall 4a, and a projection 4c extending from an end of an entire periphery of the side wall 4b. On the other hand, the second case portion 5 includes a planar wall 5a, a rectangular annular side wall 5b which extends in a perpendicular direction from an outer periphery of the planar wall 5a, a recess 5c which is positioned at and formed on an entire periphery of an end surface of the side wall 5b, and a projecting wall 5d which is formed on an inner side portion of the side wall 5b.

Further, in a state that the first and second case portions 4, 5 accommodate the circuit board 1 and the electric components 2 inside thereof, the annular projection 4c is fitted into the annular recess 5c. By bonding the side walls 4b, 5b by welding using ultrasonic working while maintaining the above-mentioned fitting engagement state, the first and second case portions 4, 5 are bonded to each other thus forming the case 3.

Further, although the annular side walls 4b, 5b have suitable portions thereof partially welded to each other, the annular side walls 4b, 5b may have entire peripheries thereof welded to each other.

Further, when the first and the second case portions 4, 5 are bonded, the projecting wall 5d of the second case portion 5 extends toward the wall 4a along the inner side of the side wall 4b of the first case portion 4 thus forming a state in which the circuit board 1 is sandwiched by an end of the projecting wall 5d and the planar wall 4a of the first case portion 4. Further, although not shown in the drawing, the end of the projecting wall 5d is brought into contact with a conductive pattern for grounding which is formed on the circuit board 1 so that static electricity which is propagated to the projecting wall 5d is made to flow into the conductive pattern.

The card-type electronic circuit unit C1 having such a constitution can be inserted into and removed from an external device 7 of a personal computer or the like, for example, and when the card-type electronic circuit unit C1 is inserted into the external device 7, a state in which the circuit board 1 is connected to the external device 7 is established.

Then, with the use of the card-type electronic circuit unit C1, data is transmitted from this external device 7 to another external device (not shown in the drawing) or this external device 7 receives data from another external device (not shown in the drawing) whereby data communication is performed between this external device 7 and the other external device.

Further, at the time of pulling out or inserting the card-type electronic circuit unit C1, the card-type electronic circuit unit C1 is held in a hand. Here, the side walls 4b, 5b of the first and second case portions 4, 5 assume the concave-convex fitting state due to the projection 4c and the recess 5c and hence, the creeping distance between the inner and outer portions of the case 3 is elongated whereby the propagation of static electricity into the accommodating portion 6 can be prevented and the rupture of the electric circuit on the circuit board 1 can be reduced.

In the above-mentioned embodiment, although the projection 4c and the recess 5c are annularly formed along the entire peripheries of the side walls 4b, 5b, the fitting portion consisting of the projection 4c and the recess 5c may be partially provided at a portion where the electric circuit is positioned close to the side wall or at a portion where the electric components 2 such as IC parts which are liable to be easily broken by static electricity are positioned.

Further, although a case in which the projection 4c is formed on the first case portion 4 and the recess 5c is formed on the second case portion 5 has been explained, the projection 4c may be formed on the second case portion 5 and the recess 5c may be formed on the first case portion 4.

As has been described heretofore, the card-type electric circuit unit according to the present invention can be inserted into or removed from the external device 7 and includes the circuit board 1 which is connectable to the external device 7, the electric components 2 which are mounted on the circuit board 1 and constitute a desired electric circuit, and the case 3 which accommodates the electric components 2 and the circuit board 1 therein. The case 3 is constituted of the first and the second case portions 4, 5 and these first and second case portions 4, 5 respectively include the planar walls 4a, 5a and the annular side walls 4b, 5b which extend in the perpendicular direction from the outer peripheries of these walls 4a, 5a. One of the first and the second case portions 4, 5 is provided with the projection 4c extending from the end of the side wall and the other of the first and second case portions 4, 5 is provided with the recess 5c which is positioned on the end surface of the side wall. The first and second case portions 4, 5 are bonded to each other in the state that the projection 4c is fitted into the recess 5c thus forming the concave-convex fitting state whereby the creeping distance between the inner and outer portions of the case 3 can be elongated compared to the prior art. Accordingly, the propagation of static electricity to the inside of the accommodating portion 6 can be prevented so that the rupture of the electric circuit on the circuit board 1 can be reduced.

Further, since the projection 4c and the recess 5c are formed over the entire peripheries of the annular side walls 4b, 5b, the creeping distance is elongated over the entire periphery of the case 3 whereby the rupture of the electric circuit on the circuit board 1 can be reduced more effectively.

Further, the first case portion 4 includes the projection 4c, the side wall 5b of the second case portion 5 having the recess 5c includes the projecting wall 5d extending along the inner side of the side wall 4b of the first case portion 4, and the circuit board 1 is sandwiched by the end of the projection wall 5d and the first case portion 4 so that the inside of the case 3 is protected by the projection wall 5d. Accordingly, it is possible to provide the card-type electronic circuit unit which can further reduce the rupture of the electric circuit on the circuit board 1.

Still further, the first case portion 4 includes the projection 4c, the side wall 5b of the second case portion 5 having the recess 5c includes the projecting wall 5d extending along the inner side of the side wall 4b of the first case portion 4, and the end of the projecting wall 5d is brought into contact with the conductive pattern for grounding which is mounted on the circuit board 1. Accordingly, static electricity which is propagated to the projection wall 5d is made to flow into the conductive pattern for grounding so that there is no possibility that static electricity is propagated to the inside of the case 3 whereby it is possible to provide the card-type electronic circuit unit which can reduce the rupture of the electric circuit on the circuit board 1.

What is claimed is:

1. A card-type electronic circuit unit capable of being inserted into or removed from an external device and comprising a circuit board which is connectable to the external device, electronic components which are mounted on the circuit board and constitute a given electric circuit, and a case which accommodates the electric components and the circuit board therein, wherein
the case is constituted of a first and a second case portions,
wherein the first and the second case portions respectively include planar walls and annular side walls which extend in a perpendicular direction from outer peripheries of the walls,
wherein one of the first and second case portions includes a projection extending from an end of the side wall,
wherein the other of the first and second case portions includes a recess positioned at an end surface of the side wall, and
wherein the first and second case portions are bonded to each other in a state that the projection is fitted into the recess.

2. A card-type electronic circuit unit according to claim 1, wherein the projection and the recess are formed on entire peripheries of the annular side walls.

3. A card-type electronic circuit unit according to claim 1, wherein the first case portion includes the projection,
wherein the side wall of the second case portion which includes the recess includes a projecting wall which extends along an inner side of the side wall of the first case portion, and
wherein the circuit board is sandwiched by an end of the projecting wall and the first case portion.

4. A card-type electronic circuit unit according to claim 1, wherein the first case portion includes the projection,
wherein the side wall of the second case portion which includes the recess includes a projecting wall which extends along an inner side of the side wall of the first case portion, and
wherein an end of the projecting wall is brought into contact with a conductive pattern for grounding which is formed on the circuit board.
